(19) United States
(12) Patent Application Publication
(10) Pub. No.: US 2010/0317195 A1
(43) Pub. Date: Dec. 16, 2010

(54) METHOD FOR FABRICATING AN APERTURE

(76) Inventors: Chih-Wen Feng, Tainan County (TW); Pei-Yu Chou, Tainan County (TW); Jiunn-Hsiung Liao, Tainan Hsien (TW); Ying-Chih Lin, Tainan City (TW); Feng-Yi Chang, Chiayi County (TW); Meng-Chun Lee, Taichung County (TW)

Correspondence Address: NORTH AMERICA INTELLECTUAL PROPERTY CORPORATION, P.O. BOX 506, MERRIFIELD, VA, 22116, US

(21) Appl. No.: 12/481,583

(22) Filed: Jun. 10, 2009

(51) Int. Cl. H01L 21/306

(52) U.S. Cl. 438/702; 257/E21.219

(57) ABSTRACT

A method for fabricating an aperture is disclosed. The method includes the steps of: depositing a dielectric layer and a hard mask on surface of a semiconductor substrate; patterning the hard mask by forming an aperture in the hard mask; utilizing a gas containing CₐX_{b} and C_{d}HXₑ to perform a pre-treatment on the patterned hard mask and the dielectric layer, in which a, b, d and e from CₐX_{b} and C_{d}HXₑ are integers and X represents halogen atom; and performing an etching process to transfer the aperture into the dielectric layer.

### BACKGROUND OF THE INVENTION

1. Field of the Invention

The invention relates to a method for fabricating an aperture, and more particularly, to a method for fabricating an aperture in a stacked dielectric film while preventing the occurrence of bowing profile on sidewall of the dielectric film where the aperture is being formed.

2. Description of the Prior Art

The trend to micro-minituriaztion, or the ability to fabricate semiconductor devices with features smaller than 0.1 micrometers, has presented difficulties when attempting to form narrow diameter, deep (high aspect ratio) contact holes in a dielectric layer, to expose underlying conductive regions.

Referring to FIG. 1, FIG. 1 illustrates a method for fabricating a contact hole according to the prior art. As shown in FIG. 1, a semiconductor substrate (not shown) having a plurality of semiconductor devices thereon is provided, in which the semiconductor device could include metal-oxide semiconductor (MOS) transistors or resistors. A dielectric layer 12 is then deposited on the aforementioned semiconductor devices. A patterned mask, such as a patterned photoresist 14 is formed on the dielectric layer 12 while exposing a part of the dielectric layer 12 and an etching process is performed by using the patterned photoresist 14 as mask to form a contact hole 16 in the dielectric layer 12. The etching process preferably uses plasma containing various gas compositions to remove a portion of the dielectric layer for exposing the semiconductor device on the semiconductor substrate, such as the source/drain regions of the MOS transistors.

As the contact hole 16 is formed in the dielectric layer 12 through the plasma etching process, molecules within the etching gas are first bombarded by high energy electrons within the plasma to generate numerous ions. These ions are then utilized to strike the dielectric layer 12 for producing volatile compounds. As the patterned photoresist 14 is disposed around the aperture 16, it should be noted that plasma ions are often rebounded to land on sidewall of the dielectric layer 12 contacting the contact hole 16. This causes severe indentation with respect to the central region of the sidewall and ultimately produces a bowing profile 18. Unfortunately, metal deposited in the contact hole 16 thereafter is likely to seal the entrance of the hole 16 before filling the expanding bowing portion 18 of the contact hole 16. Ultimately, a seam is formed relative to the central region of the deposited metal, which degrades the electrical connection of the device and affects the overall performance.

### SUMMARY OF THE INVENTION

It is an objective of the present invention to provide a method for fabricating an aperture, such a contact hole within a stacked dielectric film. The method of the present invention preferably protects the sidewall of the dielectric films from ion bombardment during etching of the contact hole and also prevents the occurrence of bowing profile in the sidewall of the dielectric films.

The method includes the steps of: depositing a dielectric layer and a hard mask on surface of a semiconductor substrate; patterning the hard mask by forming an aperture in the hard mask; utilizing a gas containing CₐX_{b} and C_{d}HXₑ to perform a pre-treatment on the patterned hard mask and the dielectric layer, in which a, b, d and e from CₐX_{b} and C_{d}HXₑ are integers and X represents halogen atom; and performing an etching process to transfer the aperture into the dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a method for fabricating a contact hole according to the prior art.

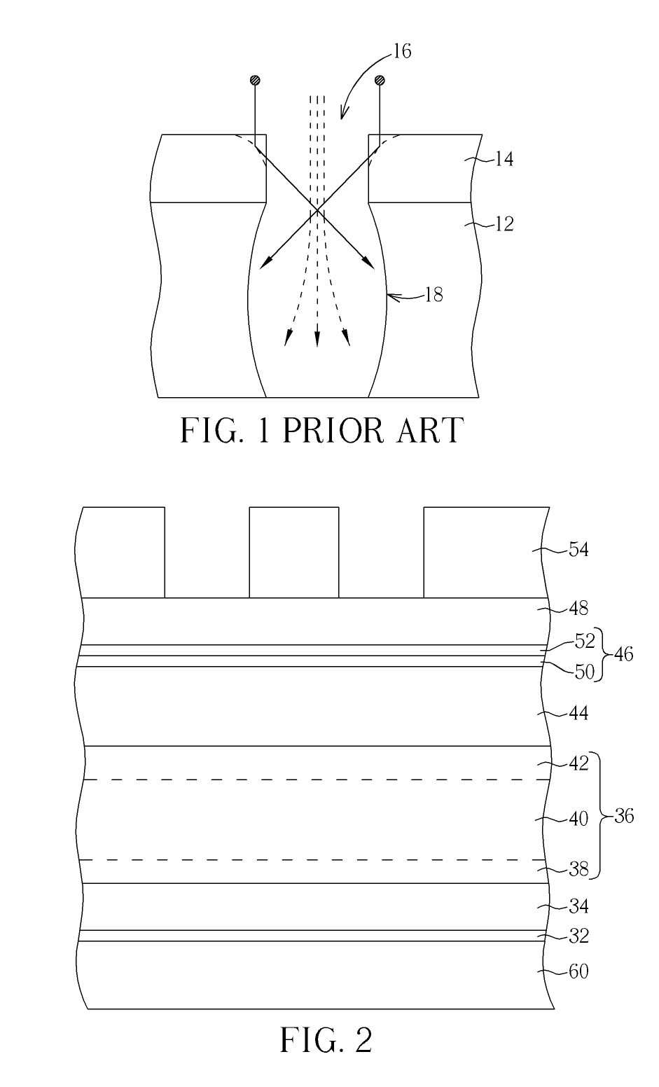

FIGS. 2-3 illustrate a method for fabricating an aperture according to a preferred embodiment of the present invention.

### DETAILED DESCRIPTION

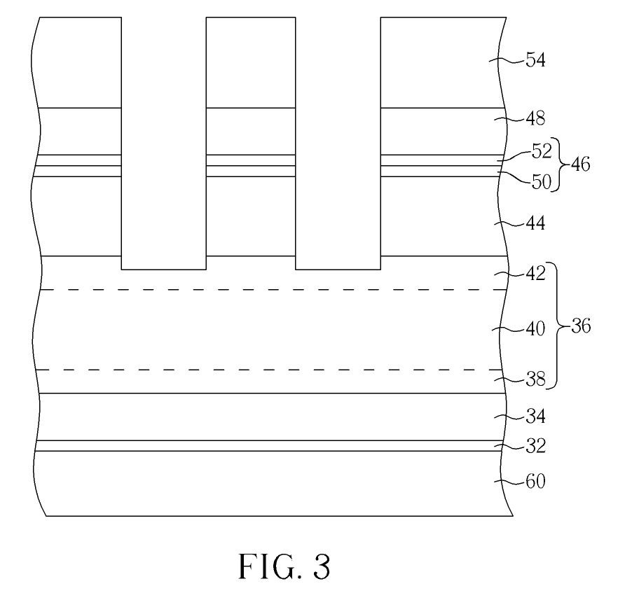

Referring to FIGS. 2-3, FIGS. 2-3 illustrate a method for fabricating an aperture according to a preferred embodiment of the present invention. As shown in FIG. 2, a semiconductor substrate 60, such as a substrate composed of monocrystalline silicon, gallium arsenide (GaAs) or other known semiconductor material is provided. A standard metal-oxide semiconductor (MOS) transistor fabrication is performed to form at least one MOS transistor (not shown) or other semiconductor devices on the semiconductor substrate 60. The MOS transistor could be a PMOS transistor, a NMOS transistor, or a CMOS transistor, and the MOS transistor could also include typical transistor structures including gate, spacer, lightly doped drains, source/drain regions and/or salicides.

A buffer layer 32 composed of oxides and a contact etch stop layer (CESL) 34 composed of nitrides is then deposited on the MOS transistors. The depth of the buffer layer 32 is preferably 50 angstroms while the depth of the contact etch stop layer 34 is preferably 850 angstroms. The buffer layer 32 and the contact etch stop layer 34 could be formed selectively, and the contact etch stop layer 34 could be formed to provide stress to the device underneath. For instance, the contact etch stop layer 34 could be a SiC layer providing tensile stress for NMOS transistors, or a SiN layer providing compressive stress for PMOS transistors. If a STI or non-transistor device is disposed underneath, the contact etch stop layer could be a composite contact etch stop layer consisting of tensile CESL and compressive CESL, and a buffer layer is further inserted between the tensile CESL and the compressive CESL.

An interlayer dielectric layer 36 is formed on surface of the contact etch stop layer 34. In this embodiment, the interlayer dielectric layer 36 is preferably composed of three layers, including a dielectric layer 38 deposited by sub-atmospheric pressure chemical vapor deposition (SACVD), a phosphosilicate glass (PSG) layer 40, and a tetraethylorthosilicate (TEOS) layer 42. The depth of the entire interlayer dielectric layer 36 is a few thousand angstroms, and preferably at approximately 3150 angstroms; the depth of the dielectric layer 38 is around several thousands of angstroms, and preferably at 250 angstroms; the depth of the PSG layer 40 is between 1000 angstroms to 3000 angstroms, and preferably at 1900 angstroms; and the depth of the TEOS layer 42 is between 100 angstroms to 2000 angstroms, and preferably at 1000 angstroms. In addition to be a composite material layer, the interlayer dielectric layer 36 could also be a single material layer, and in addition to the aforementioned materials, the interlayer dielectric layer 36 could also include undoped silicate glass (USG), borophosposilicate glass (BPSG), low-k dielectric material such as porous dielectric material, SiC, SiON, or combination thereof.

Next, a hard mask 44 is formed on surface of the interlayer dielectric layer 36. According to a preferred embodiment of the present invention, the hard mask 44 is selected from an advanced pattern film (APF) fabricated by Applied Materials Inc., in which the depth of the hard mask 44 is between 1000 angstroms to 5000 angstroms, and preferably at 2000 angstroms. A dielectric anti-reflective coating (DARC) 46 and a bottom anti-reflective coating (BARC) 48 are then deposited on surface of the hard mask 44. In this embodiment, the dielectric anti-reflective coating 46 is preferably composed of a silicon oxynitride (SiON) layer 50 and an oxide layer 52, in which the depth of the silicon oxynitride layer 50 is approximately 200 angstroms, the depth of the oxide layer 52 is approximately 50 angstroms, and the depth of the bottom anti-reflective coating 48 is approximately 1020 angstroms. The anti-reflective coating 46 and the bottom anti-reflective coating 48 are formed selectively, and in addition to inorganic materials, these two layers 46 and 48 could also be composed of organic materials by spin-coating process.

A plurality of pattern transfer processes is then performed on the above stacked film to form an aperture penetrating the bottom anti-reflective coating 48, the dielectric anti-reflective coating 46, the hard mask 44, the interlayer dielectric layer 36, the contact etch stop layer 34, and the buffer layer 32 to expose the MOS transistor underneath, such as the source/drain region of the MOS transistor. First, a patterned photoresist 54 adapted for the wavelength of approximately 193 nm is formed on the aforementioned stacked film to expose a portion of the upper surface of the stacked film, in which the depth of the patterned photoresist 54 is approximately 1800 angstroms. A descum process is performed thereafter by using a gas containing CO and O₂ to remove excessive particles produced from exposure and development process.

As shown in FIG. 3, the patterned photoresist 54 is used as mask to perform a pattern transfer process on the bottom anti-reflective coating 48. Preferably, an etching gas containing CF₄ and CH₂F₂ is utilized to remove a portion of the bottom anti-reflective coating 48 and the dielectric anti-reflective coating 46 for transferring the aperture pattern of the patterned photoresist 54 to the bottom anti-reflective coating 48 and the dielectric anti-reflective coating 46 and exposing the hard mask 44 underneath. CF₄ used in this patterning process is utilized as a main etching gas while CH₂F₂ is utilized as a protective gas for protecting the sidewall of the etched target. For instance, CF₄ is preferably utilized to remove major portion of the bottom anti-reflective coating 48 and the dielectric anti-reflective coating 46 during the patterning process while transferring the aperture pattern of the patterned photoresist 54 to the two layers 48 and 46. CH₂F₂ on the other hand is used to react with the layers 48 and 46 for accumulating polymers on the etched sidewall of the layers 48 and 46. This effectively protects the sidewall of the etching target from ion bombardment during the etching process and also prevents the occurrence of bowing profile on the sidewall.

Next, the patterned photoresist 54 is used as a mask to perform another pattern transfer process. Preferably, a gas containing CO and O₂ is used to remove a portion of the hard mask 44 by transferring the aperture pattern of the bottom anti-reflective coating 48 and the dielectric anti-reflective coating 46 to the hard mask 44. In this embodiment, the step of utilizing gas containing CO and O₂ to pattern the hard mask 44 would remove the patterned photoresist 54 and the bottom anti-reflective coating 48 simultaneously.

A pre-treatment is then conducted by using a gas containing CₐX_{b} and C_{d}HXₑ on the patterned hard mask 44 and the interlayer dielectric layer 36, in which a, b, d and e from CₐX_{b} and C_{d}HXₑ are integers and X represents halogen atom. According to a preferred embodiment of the present invention, CₐX_{b} includes CF₄ while C_{d}HXₑ includes CHF₃. Similar to the aforementioned step of patterning the bottom anti-reflective coating 48 and the dielectric anti-reflective coating 46, CF₄ used in this patterning process is utilized as a main etching gas while CHF₃ is utilized as a protective gas for protecting the sidewall of the target. For instance, CF₄ is preferably utilized to remove the dielectric anti-reflective coating 46, a portion of the remaining hard mask 44 until exposing the surface of the interlayer dielectric layer 36, and a small portion of the interlayer dielectric layer 36 during the patterning process while transferring the aperture pattern of the dielectric anti-reflective coating 46 to the hard mask 44 and the upper portion of the interlayer dielectric layer 36. CHF₃ on the other hand is used to react with the hard mask 44 and interlayer dielectric layer 36 for accumulating polymers on the etched sidewall of the layers 44 and 36. This effectively protects the sidewall of the etching target from ion bombardment during the etching process and also prevents the occurrence of bowing profile on the sidewall.

Next, the hard mask 44 is used as a mask to perform a pattern transfer process on the interlayer dielectric layer 36. Preferably, a gas containing C₄F₆, O, and Ar is used to remove a portion of the interlayer dielectric layer 36 while transferring the aperture pattern of the hard mask 44 to the TEOS layer 42, PSG layer 40, and dielectric layer 38 of the interlayer dielectric layer 36.

Next, the patterned hard mask 44 is used as a mask to perform a pattern transfer process on the contact etch stop layer 34 under the interlayer dielectric layer 36. Preferably, a gas containing CH₂F₂, O, and Ar are used to remove major portion of the contact etch stop layer 34 while transferring the aperture pattern of the hard mask 44 to the contact etch stop layer 34. Thereafter, O₂ is used as an etching gas to remove the hard mask 44, and a gas containing CH₃F, O, and Ar is used to perform a second stage pattern transfer for transferring the aperture pattern of the interlayer dielectric layer 36 to the contact etch stop layer 34 and exposing the buffer layer 32 underneath. Next, another pattern transfer is conducted on the buffer layer 32 by using a gas containing CF₄, CHF₃, and Ar to remove a portion of the buffer layer 32 while transferring the aperture pattern of the contact etch stop layer 34 to the buffer layer 32 and exposing the semiconductor device underneath, such as the source/drain region of the MOS transistor. This completes a method for fabricating an aperture within a stacked dielectric film according to a preferred embodiment of the present invention.

The aforementioned etching processes could be performed in-situly in the same etching equipment, performed ex-situly in different etching equipments, or some steps performed in-situly in same etching equipment while the rest steps performed ex-situly in different etching equipments. Moreover, all of the aforementioned etching process could all be performed according to an end-point detecting method or a following a time-mode, which are all within the scope of the present invention.

Overall, the present invention deposits a plurality of dielectric films on top of the semiconductor device and uses a gas containing CₐX_{b} and C_{d}HXₑ to pattern an aperture in the stacked dielectric films, in which CₐX_{b} includes CF₄ while C_{d}HXₑ includes CHF₃ or CH₂F₂. As illustrated in the previous embodiments, a gas containing CF₄ and CH₂F₂ could be utilized in the patterning of the bottom anti-reflective coating, whereas a gas containing CF₄ and CHF₃ could be utilized in the patterning of the hard mask and the interlayer dielectric layer underneath. CF₄ used in this patterning process is utilized as a main etching gas while CH₂F₂ is utilized as a protective gas for protecting the sidewall of the target. By using the aforementioned gas composition to form an aperture in the stacked dielectric films, the present invention could accumulate polymers on sidewall of the etched layers, which preferably protects the sidewall of the dielectric films from ion bombardment during the etching process and also prevents the occurrence of bowing profile.

Those skilled in the art will readily observe that numerous modifications and alterations of the device and method may be made while retaining the teachings of the invention.

What is claimed is:

1. A method for fabricating an aperture, comprising:
depositing a dielectric layer and a hard mask on surface of a semiconductor substrate;
patterning the hard mask by forming an aperture in the hard mask;
utilizing a gas containing CₐX_{b} and C_{d}HXₑ to perform a pre-treatment on the patterned hard mask and the dielectric layer, wherein a, b, d and e from CₐX_{b} and C_{d}HXₑ are integers and X represents halogen atom; and
performing an etching process to transfer the aperture into the dielectric layer.

2. The method of claim 1, wherein the hard mask comprises amorphous carbon.

3. The method of claim 1, wherein CₐX_{b} comprises CF₄.

4. The method of claim 1, wherein C_{d}HXₑ comprises CHF₃.

5. The method of claim 1, further comprising a patterned photoresist and an antireflective layer on the hard mask after depositing the dielectric layer and the hard mask.

6. The method of claim 1, wherein the dielectric layer comprises a tetraethylorthosilicate (TEOS) layer and a phosphosilicate glass (PSG) layer.

7. The method of claim 1, wherein the depth of the hard mask is between 1000 angstroms to 5000 angstroms.

8. The method of claim 6, wherein the depth of the TEOS layer is between 100 angstroms to 2000 angstroms.

9. The method of claim 6, wherein the depth of the PSG layer is between 1000 angstroms to 3000 angstroms.

10. The method of claim 1, further comprising utilizing C₄F₆, O₂ and Ar for performing the etching process to transfer the aperture into the dielectric layer.

11. The method of claim 1, further comprising utilizing CO and O₂ for patterning the hard mask.

12. The method of claim 1, further comprising performing the etching process in-situly.

13. The method of claim 1, further comprising performing the etching process ex-situly.
